(19) United States
(12) Patent Application Publication
(10) Pub. No.: US 2020/0058812 A1
(43) Pub. Date: Feb. 20, 2020

(54) SHINGLED ARRAY MODULE FOR VEHICLE SOLAR ROOF

(71) Applicant: FLEX LTD, Singapore (SG)

(72) Inventor: Lisong Zhou, Fremont, CA (US)

(21) Appl. No.: 16/327,626

(22) PCT Filed: May 11, 2018
(86) PCT No.: PCT/US2018/032329

§ 371 Date: Feb. 22, 2019

Related U.S. Application Data
(60) Provisional application No. 62/505,581, filed on May 12, 2017.

(51) Int. Cl. H01L 31/048; H01L 31/0443; H01L 31/05; B60L 8/00

(52) U.S. Cl. CPC H01L 31/0488; B60L 8/003; H01L 31/0504; H01L 31/0443

(57) ABSTRACT

A solar module for incorporation in a motor vehicle including a front sheet having a curvature in at least two directions, at least one set of strings, wherein each string is formed of a plurality strips of a solar cell, and each of the strips is arranged in an overlapping manner with an adjacent strip, and electrically connected to an adjacent strip with an electrically conductive adhesive. The module further includes a first encapsulation layer disposed between the front sheet and a first side of the at least one set of strings, a second encapsulation layer formed on a second side of the ate least one set of strings, and a back sheet formed on the second encapsulation layer.

### BACKGROUND

### 1. Technical Field

The present disclosure relates to a solar module for incorporation into motor vehicles and, more specifically, to a shingled solar module for incorporation into motor vehicles.

### 2. Related Art

A variety of techniques and devices have been contemplated for incorporation of a solar module or solar panel into an automobile. However, as can be appreciated, the roof or body of most motor vehicles is relatively small and, as a result, the power output from solar panels on these relatively small roofs is limited. Moreover, in many instances if the solar panel is shaded more than about 10-15% of its total surface, the output of the solar module drops significantly. Another challenge faced by application of solar technology to motor vehicles is the fact that the roof of most vehicles is not flat but rather has a curvature. Most solar modules, however, are designed and fabricated for flat application to roofs and solar tracker arrays.

In a typical vehicle solar arrangement as depicted in FIG. 1, pseudo-square cells (though square cells could be used as well), larger areas of metal (often foil), or another bendable material are used. This metallization allow for interconnection of the cells and provides the flexibility for the square rigid cell to be utilized in an otherwise rounded form factor. However, as can be appreciated, every square centimeter of the surface of the solar module covered by metallization patterns is surface area which cannot be used by the cell for the purposes of converting sunlight to electrical energy. As seen in FIG. 1, these metallization patterns can result in a loss of effective area of a module of 5 and up to 10% of the total area. In commercial and residential settings this loss is made-up for by adding additional panels, but that is not an option in the motor vehicle setting and, as a result, improvements over the known solar modules for vehicles is needed.

### SUMMARY

The present disclosure is directed to a solar module for incorporation in a motor vehicle. The solar module includes a front sheet having a curvature in at least one direction, at least one set of strings, wherein each string is formed of a plurality strips of a solar cell and each of the strips is arranged in an overlapping manner with an adjacent strip and electrically connected to an adjacent strip with an electrically conductive adhesive, and a first encapsulation layer disposed between the front sheet and a first side of the at least one set of strings. The solar module also includes a second encapsulation layer formed on a second side of the at least one set of strings, and a back sheet formed on the second encapsulation layer.

The plurality strings may be electrically connected in parallel, and the solar module may include two sets of strings, wherein each set is electrically connected in series. The solar module may include a plurality of bypass diodes, and each string may include a bypass diode.

In accordance with one aspect of the present disclosure, the front sheet may be formed of glass. Further, the back sheet may be formed of a flat transparent material. Still further, the back sheet may have sufficient flexibility to mold to the profile of the other layers during a lamination process.

In yet a further aspect, upon lamination, the first and second encapsulation layers fill any gaps and voids formed by the overlapping strips or the spacing between adjacent strings. Further, upon lamination, the first and second encapsulation layers adhere the front sheet and back sheet to sets of strings forming a unitary construction for the solar module.

In accordance with a further aspect of the present disclosure, the strips overlap at bus bars formed on a front side and a back side of each strip to create an electrical circuit along the length of the string. Further, each string may electrically connect to a bus bar formed on each end of the solar module. Still further, the sets of strings may be arranged to substantially conform to the curvature of the front sheet.

Further, in an aspect of the disclosure, the solar module includes at least one positive and at least one negative electrical terminal for connection to an electrical storage element of a motor vehicle. The electrical storage element may be a battery.

### BRIEF DESCRIPTION OF THE FIGURES

Objects and features of the presently disclosed system and method will become apparent to those of ordinary skill in the art when descriptions of various embodiments thereof are read with reference to the accompanying drawings, of which:

FIG. 1 is a perspective view of a known installation of a solar module deployed on a motor vehicle;

FIG. 2 is a perspective view of a solar module in accordance with the present disclosure as deployed on a motor vehicle;

FIG. 3 is a perspective view of a solar cell in accordance with the present disclosure;

FIG. 4 a perspective view of an alternative solar cell in accordance with the present disclosure;

FIG. 5 is a back view of the solar cell of FIG. 4;

FIG. 6 is an alternative back view of the solar cell of FIG. 4;

FIG. 7 is a further alternative metallization pattern that may be employed on either a front or back of the solar cell of FIG. 4;

FIG. 8 is a front view of a singulated solar cell in accordance with the present disclosure;

FIG. 9 is a side view of shingled strips of solar cells in accordance with the present disclosure;

FIG. 10 is a top view of shingled strips from pseudo-square solar cells forming a string in accordance with the present disclosure;

FIG. 11 is a top view of shingled strips from a square solar cell forming a string in accordance with the present disclosure;

FIG. 12 is a longitudinal cross-sectional view of a solar module in accordance with the present disclosure;

FIG. 13 is a transverse cross-sectional view of a solar module in accordance with the present disclosure;

FIG. 14 is an electrical schematic of a solar module in accordance with the present disclosure;

FIG. 15 is an alternative electrical schematic of a solar module in accordance with the present disclosure;

FIG. 16 is another alternative electrical schematic of a solar module in accordance with the present disclosure; and

FIG. 17 is a simplified cross-sectional view of a solar module in accordance with the present disclosure.

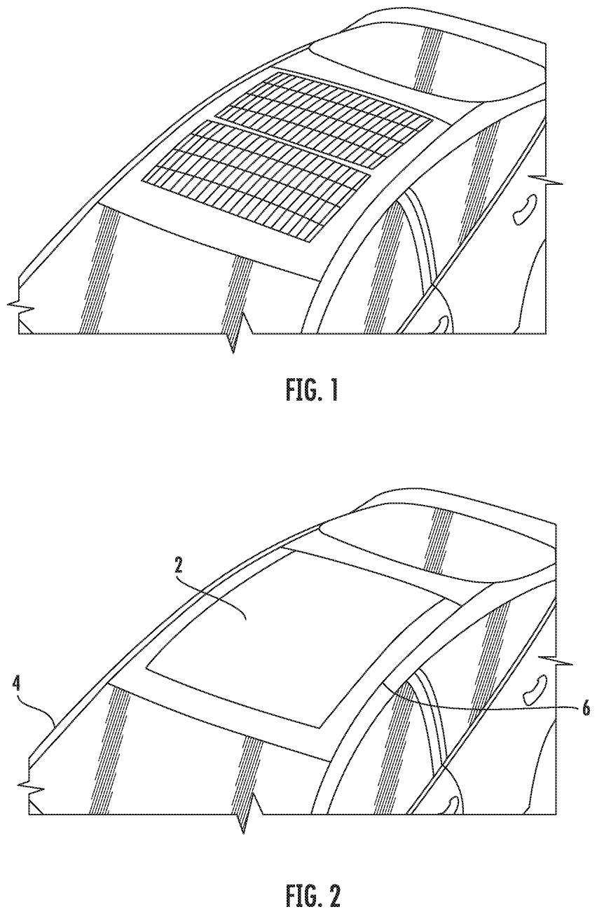

### DETAILED DESCRIPTION

The present disclosure incorporates herein by reference International Application No. PCT/CN2017/076017 filed Mar. 9, 2017 entitled “Shingled Array Solar Cells and Methods of Manufacturing Solar Modules Including the Same” to Zhou et al. in its entirety, as if fully set forth here.

FIG. 2 depicts a shingled solar module 2 in accordance with the present disclosure having been installed on a motor vehicle 4. Without close inspection, the roof 6 of the vehicle 4 would appear similar to other glass roof vehicles. The roof 6 would preferably be black and may require some mechanical support as do current glass roofs used in motor vehicles. A rubber gasket (not explicitly shown) surrounds the solar panel 2 and ensures a watertight fit within the structure of the motor vehicle 4. Further, an outer glass layer, described below, actually increases the stiffness of the roof 6 as compared to sheet metal roofs.

Shingling relates to a process of cutting a solar cell into strips, typically five (5) or six (6), though other numbers are contemplated. FIG. 3 depicts a solar cell 10, from a front side thereof. The solar cell 10 includes five (5) bus bars 12. Finger lines 14 extend across each of the portions of the solar cell 10 and terminate at the ends thereof at the edges of the solar cell 10 and/or the bus bars 12. The finger lines 14 and bus bars 12 together form a metallization pattern of the solar cell 10. Typically the metallization pattern is formed of a conductor such as silver and is printed on the solar cell 10 during manufacturing.

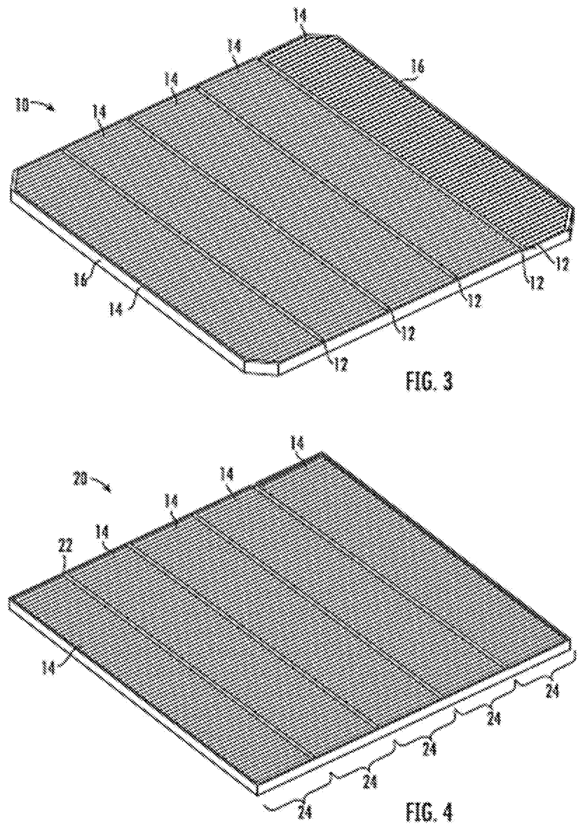

FIG. 4 depicts a front side configuration of another solar cell 20 in accordance with the present disclosure. The solar cell 20 includes finger lines 14, but no bus bars are formed on the solar cell 20. Rather, cut lines 22 separate the finger lines 14 from extending across the entirety of the solar cell 20. These cut lines 22 are the lines along which the solar cell 20 will be etched or scribed (described in greater detail below) and then separated into individual strips 24. In contrast with the solar cell 10 of FIG. 3, the solar cell 20 in FIG. 4 has a square design, whereas that of FIG. 3 has a pseudo-square design. Those of skill in the art will recognize that the embodiment of FIG. 4 may also be formed in a pseudo-square and that the embodiment of FIG. 3 may be formed in a square design, without departing from the scope of the present disclosure.

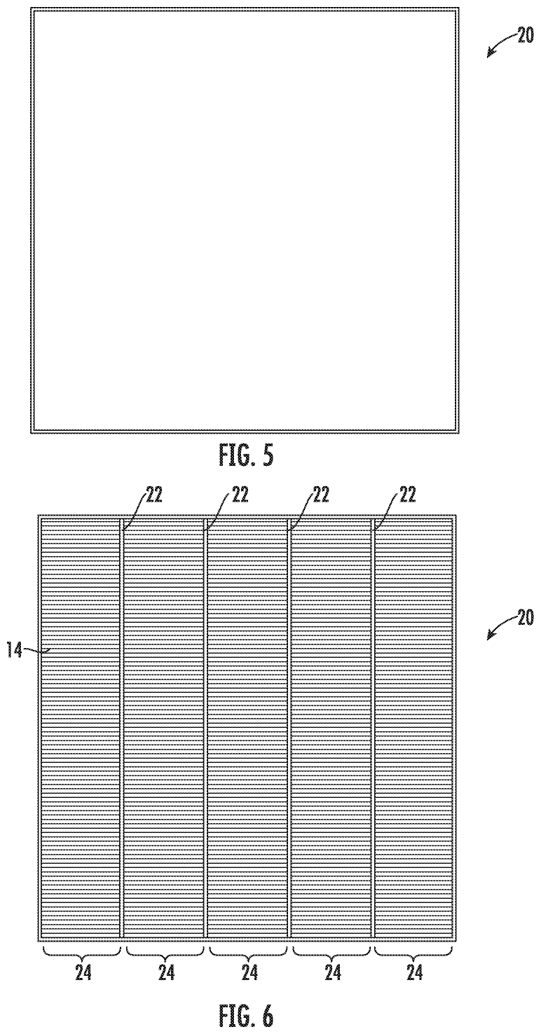

FIGS. 5 and 6 depict two different variations of a back side configuration of the solar cell 20 depicted in FIG. 4. In FIG. 5, there are no finger lines, thus a solar cell 20 having this configuration has limited, if any, ability to collect solar energy via the backside of the solar cell 20. In contrast to FIG. 5, the embodiment of FIG. 6 shows a solar cell 20 having a surface with fingers 14 formed between cut lines 22, to define individual strips 24. FIG. 6 is in fact nearly identical to FIG. 4 such that the front and back sides of the solar cell 20 so manufactured are nearly identical. Alternatively, the fingers 14 formed on the back side may have a greater density; that is there are more of them than on the front side. In addition to its ability to collect light from rear side, the rear metallization pattern in FIG. 6 is more symmetrical to the front side than in FIG. 5. Therefore, less wafer bending is expected after metallization due to less stress to the thin wafer. As a result, an even thinner wafer can be utilized for making solar cells which adding further flexibility to the strings. An example of this can be seen in U.S. Design patent application Ser. No. 29/624,485 filed Nov. 1, 2017, entitled “Solar Cell,” the entire contents of which are incorporated herein by reference.

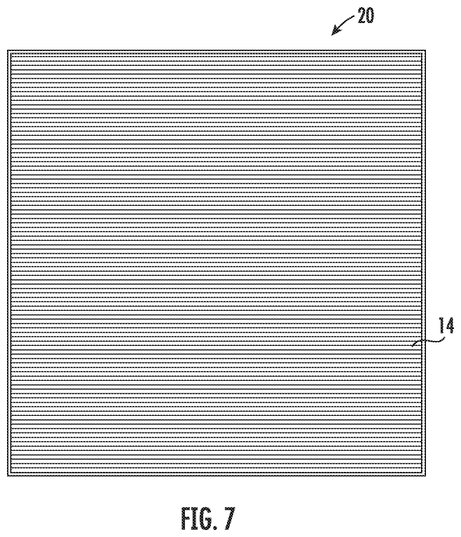

In a further embodiment, as depicted in FIG. 7, either or both of the front surface or the back surface of solar cell 20 can be formed without cut lines, and instead the fingers 14 extend the entire width across the solar cell.

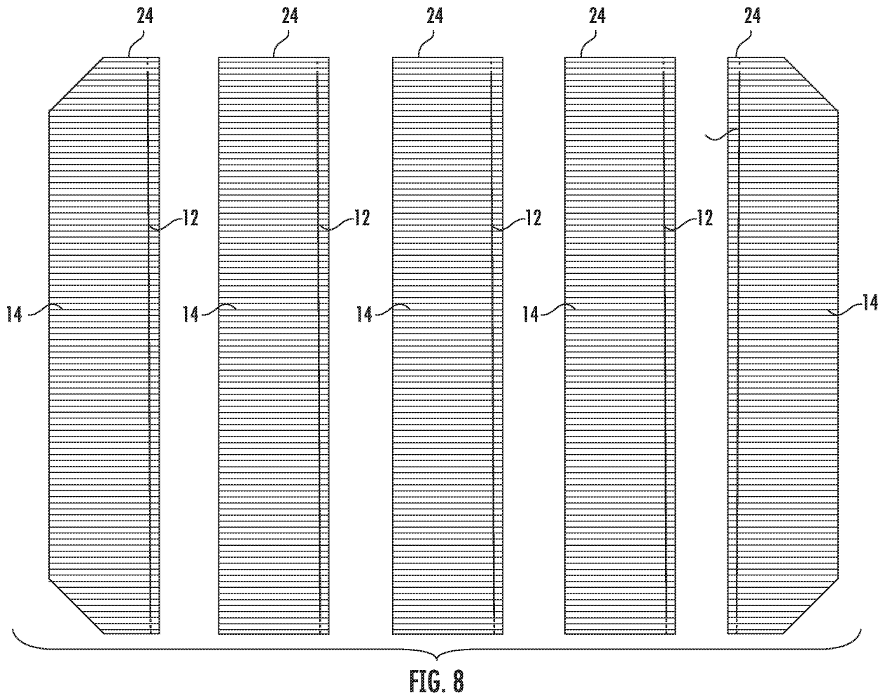

Once the solar cells 10, 20 are manufactured with the fingers 14 patterned either with or without the cut lines 22 as depicted at least in FIG. 3 or 4, the cells 10, 20 are ready to be singulated. Singulation is the breaking or separation process after etching along the cut line 22. The etching removes material, for example, in the cut line 22, to weaken the solar cell 10, 20. Each etching has a depth of between about 10% and about 90% of wafer thickness. The etching may be formed using a laser, a dicing saw, or the like. In an embodiment, the etching extends across the solar cells 10, 20 from edge to edge. In another embodiment, the scribe lines, formed by the etching, extend from one edge to just short of an opposite edge of the solar cell 10, 20. Once weakened, application of a force to the weakened areas results in the breaking of the solar cell 10, 20 along the etching to form strips 24 as depicted in FIG. 8. In the example of FIG. 8, five individual strips 24 are formed. As will be appreciated, any suitable number of strips 24, e.g., 3, 4, 5, or 6 strips, can be formed during singulation depending upon the original construction of the solar cell 10, 20. Each strip 24 includes busbars 12 on opposing edges, one on the front and one on the back side. If a typical solar cell 10, 20 has a width of about 156 mm and is singulated into 5 strips 24, each strip 24 has a width dimension of about 31 mm, as shown in FIG. 8.

In order to singulate, the solar cell 10, 20 is placed on a vacuum chuck including a plurality of fixtures which are aligned adjacent each other to form a base. The vacuum chuck is selected so that the number of fixtures matches the number of discrete sections of the solar cell 10, 20 to be singulated into strips 24. Each fixture has apertures or slits, which provide openings communicating with a vacuum. The vacuum, when desired, may be applied to provide suction for temporarily mechanically coupling the solar cell 10, 20 to the top of the base. To singulate the solar cell 10, 20, the solar cell is placed on the base such that the each discrete section is positioned on top of a corresponding one of the fixtures. The vacuum is powered on and suction is provided to maintain the solar cell 10, 20 in position on the base. Next, the fixtures are moved relative to each other. In an embodiment, multiple ones of the fixtures move a certain distance away from neighboring fixtures thereby causing the discrete sections of the solar cell 10, 20 to likewise move from each other and form resulting strips 24. In another embodiment, multiple ones of the fixtures are rotated or twisted about their longitudinal axes thereby causing the discrete sections of the solar cell 10, 20 to likewise move and form resulting strips 24. The rotation or twisting of the fixtures may be effected in a predetermined sequence, in an embodiment, so that no strip 24 is twisted in two directions at once. In still another embodiment, mechanical pressure is applied to the back surface of the solar cell 10, 20 to substantially simultaneously break the solar cell 10, 20 into the strips 24. It will be appreciated that in other embodiments, other processes by which the solar cell 10, 20 is singulated may alternatively be implemented.

After the solar cell 10, 20 is singulated, the strips 24 are sorted. As will be appreciated that the two end strips 24 of a pseudo-square solar cell 10 (see, e.g., FIGS. 3, 8) will have a different shape (chamfered corners) than the center three strips 24 (rectangular) or all the strips of a square solar cell 20 (FIG. 4). Like formed strips 24 are collected and sorted together. In an embodiment, sorting strips 24 is achieved using an auto-optical sorting process. In another embodiment, the strips 24 are sorted according to their position relative to the full solar cell 10, 20. After sorting, strips 24 having chamfered corners are segregated from those strips 24 having rectangular (non-chamfered) corners. For further processing, in accordance with the present disclosure, only like strips 24 are used together (either chamfered or rectangular). Further, depending on which configuration of front and back surfaces (FIGS. 3-7, etc.) the segregation may require ensuring that the strips 24 are properly aligned with one another.

Once sorted and segregated, the strips 24 are ready to be assembled into strings 30. To form strings 30, as shown in FIG. 9, multiple strips 24 are aligned in an overlapping orientation. An electrically-conductive adhesive 32 is applied to a front surface of a strip 24 along an edge of the strip 24 and an edge along a bottom surface of a neighboring strip is placed into contact with the electrically-conductive adhesive 32 to mechanically and electrically connect the two strips 24. As will be appreciated, the electrically-conductive adhesive 32 may be applied to a back surface of a strip 24 and then placed in contact with the front surface of a neighboring strip 24. The electrically-conductive adhesive 32 may be applied as a single continuous line, as a plurality of dots, or dash lines, for example, by using a deposition-type machine configured to dispense adhesive material to a bus bar surface. In an embodiment, the adhesive 32 is deposited such that it is shorter than the length of the strip 24 and has a width and thickness to render sufficient adhesion and conductivity. The steps of applying the adhesive 32 and aligning and overlapping the strips 24 are repeated until a desired number of strips 24 are adhered to form the string 30. A string may include, for example, 10 to 100 strips.

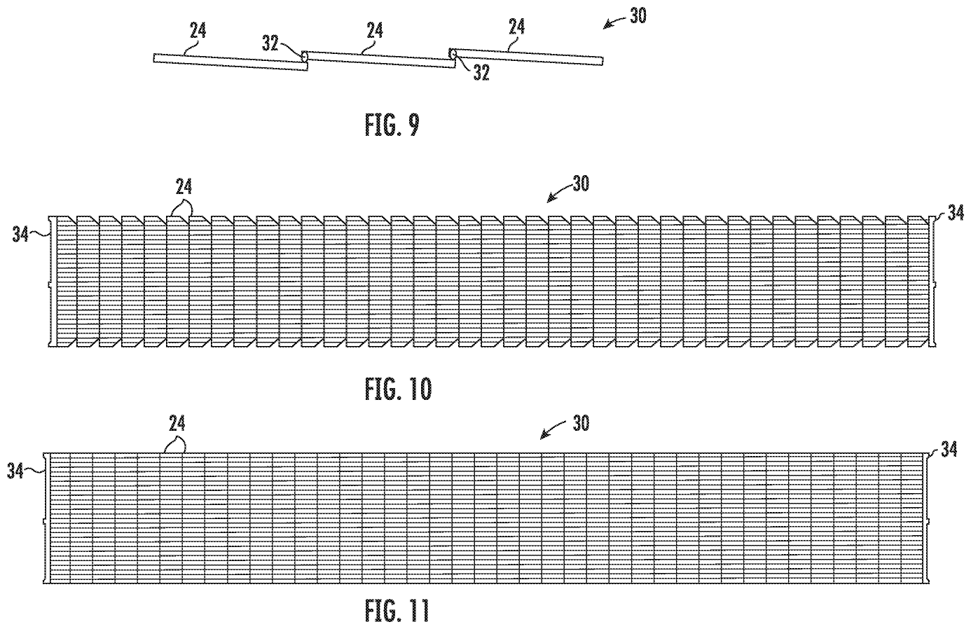

FIG. 10 depicts a top view of a string 30 formed of multiple strips 24, by the process outlined above with respect to FIG. 9. In FIG. 10, the chamfered corner strips 24 are adhered together. The end of the string 30 includes a metal foil 34 soldered or electrically connected using electrically-conductive adhesive 32 to the end strip 24. The metal foil 34 will be further connected to a module interconnect bus bar so that two or more strings together form the circuit of a solar module, as will be discussed in detail below. In another embodiment, the module interconnect bus bar can be directly soldered or electrically connected to the end strip 24 to form the circuit. In another embodiment as illustrated in FIG. 11, rectangular strips 24 are adhered to each other to form a string 30. Similar to the string 30 shown in FIG. 10, the string 30 includes, for example, 10 to 100 strips 24, with each strip 24 overlapping an adjacent strip 24. The string 30 of FIG. 11 also includes electrical connections for coupling to another similarly configured string 30.

Each 30 string has a length approximately equal to either the length or the width dimension of the final solar module and can vary depending on application. Each string 30 has a positive side and a negative side, which connect to the positive and negative bus bars (not expressly shown) of the final module 2 (FIG. 2). The strings 30 are typically connected in parallel between two bus bars.

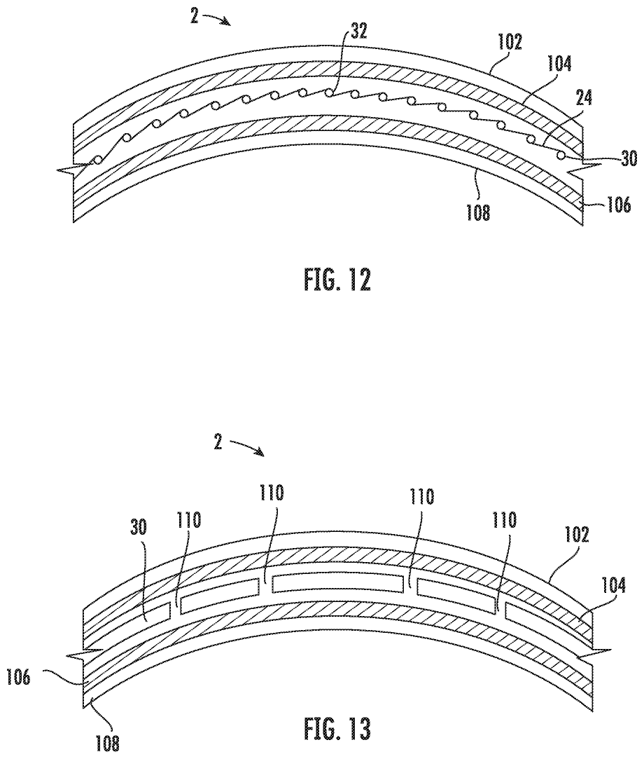

To from these strings 30 into a module 2 (FIG. 2), a top glass layer 102 is employed, as shown in FIG. 12. In a vehicle setting, this will likely be a pre-bent or pre-formed glass layer or polymeric material which will seamlessly integrate with the designed roofline of the vehicle. In the example shown in FIG. 12, the layers of a solar panel module 2 are depicted in accordance with the present disclosure. In FIG. 7 the solar panel module 2 is depicted in cross section and in an un-laminated state. A first glass layer 102 forms a protective layer for the strings 30 of strips 24; this first glass layer 102 will form the roofline of the vehicle and likely have a fore and aft curvature as depicted in FIG. 12 as well as left-right curvature as shown in FIG. 13. An encapsulation layer 104 separates the first glass layer 102 from the strings 30 of strips 24. The encapsulation layer 104 is formulated to bond with the first glass 102 and the strings 30. The encapsulation layer 104 will also fill in any gaps and spaces between the first glass layer 102 and the strings 30. As described above, the strips 24 are connected at their bus bars (front and back), or at least along their edges, with electrically conducting adhesive (ECA) 32. Because of the relatively small dimension of the strips 24 used to form the strings 30 and the use of ECA 32, the strings 30 are easily bent to match the curvature of the first glass layer 102. This also minimizes breakage of the strings 30 when applied to the curved glass layer 102. A second layer of encapsulation material 106 is formed on a second side of the strings 30, and a second glass layer 108 completes the assembly of the solar module 2.

The second glass layer 108 may be replaced by a polymer back sheet, without departing from the scope of the present disclosure. The second glass layer 108 may also be black glass and may be thinner than the first glass layer 102 since it and does not have the same mechanical requirements as the first glass layer 102. A second glass layer 108 may be employed, for example, in scenarios where greater insulative properties are needed. The second glass layer 108 may be formed of a thin and relatively flexible glass that can be formed straight and then curved to conform to the first glass layer 102 during lamination.

As depicted in FIGS. 12 and 13, the first glass layer 102 may be pre-bent to a desired shape, both fore and aft as well as left to right, to match the desired curvature of the roofline of a vehicle. The lamination process may start with the top glass layer 102 and have the encapsulation layers 104, the strings 30, encapsulation 106, and the second glass layer 108 added in order to form the solar panel 2. The application of heat and pressure cause the encapsulation layers 104, 106 to liquefy and fill any gaps in the shingling of the strips 24 forming strings 30 while still cushioning and electrically isolating the strings 30 from each other and other electrically conductive components. FIG. 13 details how multiple strings 30 are aligned with one another in a side-by-side configuration and in combination with the encapsulation layers 104, 106, when laminated form a unitary solar module 2 between the first glass layer 102 and the back sheet or second glass layer 108.

The edges of any two adjacent strings 30 are spaced apart providing a small gap 110 there between. The gap 110 has a substantially uniform width (taking into account manufacturing, material, and environmental tolerances) between the two adjacent strings 30 of about 1 mm to about 5 mm. In another embodiment, the edges of two or more of the strings 30 are immediately adjacent each other.

The strings 30 may be arranged in a number of different parallel and series connections. In one embodiment, each string 30 is connected in series to the next with a single positive and negative terminal for the solar panel module 2. Alternatively, bus bars may be employed to allow for connection of some or all of the strings 30 in parallel. The electrical connections may depend on the vehicle, its battery charging voltages, and the minimization of shadowing effects.

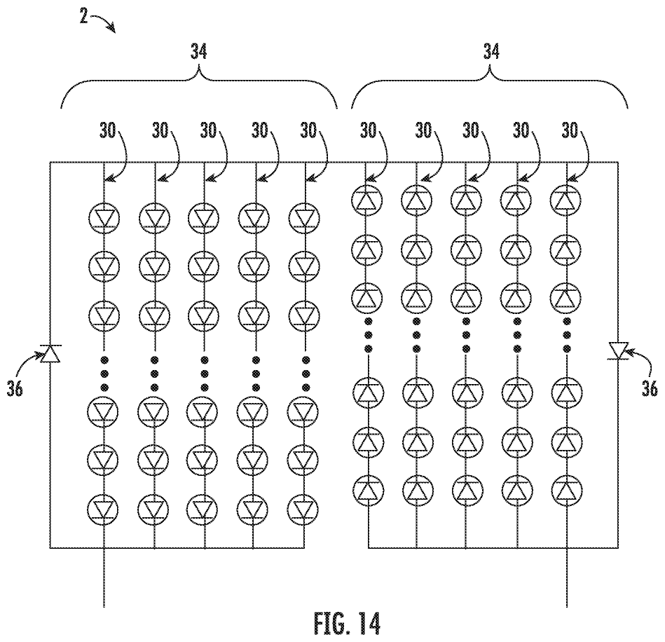

For example, turning to FIG. 14, an electrical schematic for solar module 2 is provided, where ten strings 30 are grouped into two sets 34 of strings 30. The strings 30 of the first set of strings 34 are connected in parallel with each other and with a bypass diode 36. Similarly, the strings 30 of the second set 34 of strings 30 are connected in parallel with each other and with a bypass diode 36. The two sets 34 of strings 30 are connected in series with each other.

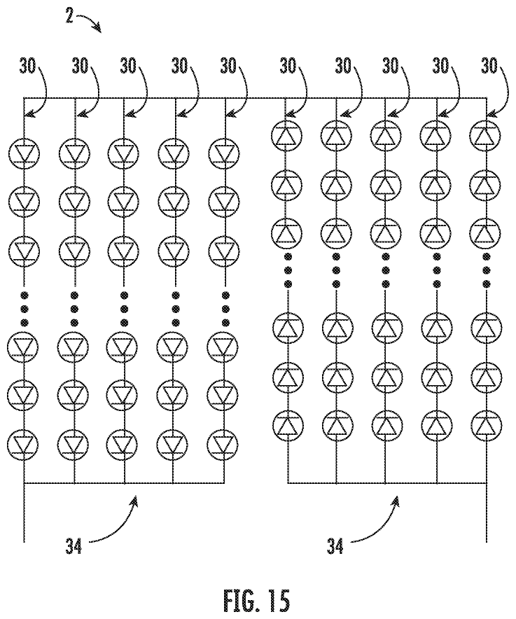

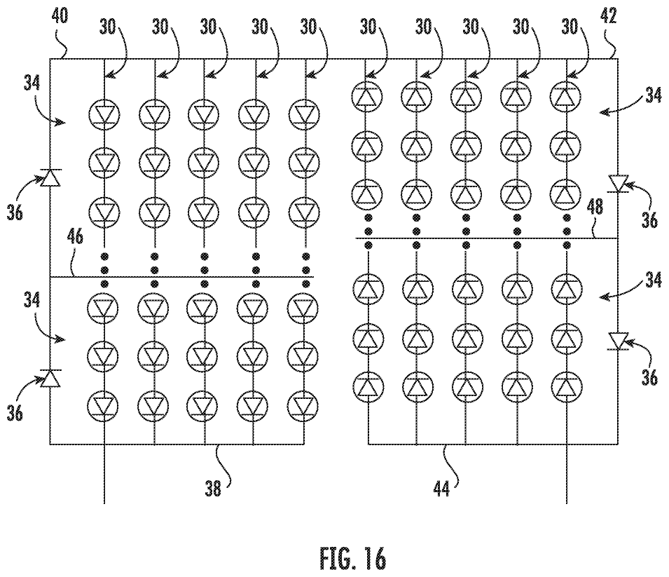

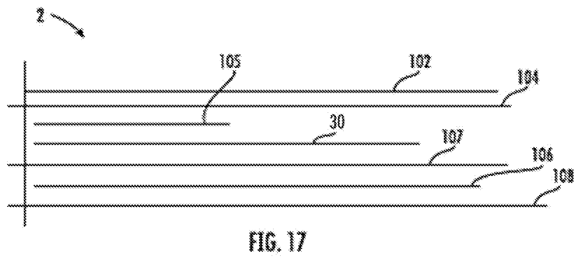

In another embodiment as illustrated in FIG. 15, an electrical schematic for solar module 2 is provided that is identical to the electrical schematic provided in FIG. 14, except no bypass diodes are included. FIG. 16 is another embodiment of an electrical schematic for solar module 2. Here, the strings 30 are grouped into four sets 34 of strings 30 which span just half the distance between the bus bars 38 and 40 and bus bars 42 and 44. In one embodiment, intermediate bus bars 46 and 48 connect two sets 34 of strings 30 in parallel. The result is four (4) sets 34 of strings 30 which are arranged in series. Within each set 54, the strings 30 are arranged in parallel as described above. As depicted in FIG. 15, each set 34 of strings 30 includes a bi-pass diode 36.

As described above, the strings 30 may be grouped together as a set 34 of strings 30. In a set 34, the strings 30 are typically arranged electrically in parallel. In some embodiments, a second set 34, also connected electrically in parallel, are grouped together and form the second half of the solar panel module 2. The sets 34 are then connected in series. At each edge of the solar panel module 2, one or more bus bars enable the electrical connection of the strings 30. In some instances an isolation strip (not shown) is disposed between the two string sets 34 to provide support. The isolation strip is sufficiently wide to permit the adjacent strings 30 of the two string sets 34, respectively, to overlap a portion of the isolation strip.

In accordance with one embodiment, the series connection of a first string set 34 to the second string set 34 can be made by attaching the negative side of the first string set 34 and the positive side of the second string set 34 to a common bus bar. Alternatively, positive sides of both the first and second string sets 34 may be placed on the same side of the solar panel module 2 and a cable, wire, or other connector may be used to electrically connect the negative side of the first string set 34 to the positive side of the second string set 34. This second configuration promotes efficiency in manufacturing by allowing all string sets 34 to be placed in the solar panel module 2 without reorientation of any of them, and reduces the size of the bus bars, as well as making all bus bars of similar length rather than having one side be long and the other side formed of two short bus bars, thus reducing the number of components of the entire solar panel module 2.

FIG. 17 is a simplified cross-sectional view of a solar panel module 2 after construction. As shown, solar module 2 has a front sheet layer 102, which serves as a top of the solar panel module 2, an EVA layer 104, a bus bar layer, which may be formed of a conductive ribbon layer 105, a set 34 of strings layer 30, an isolation strip layer 107, a rear EVA layer 106, and a back sheet layer 108. Though layers 102 and 108 are described in some instances as being formed of glass, they may also be formed of transparent polymers and other materials other than glass without departing from the scope of the present disclosure.

A power optimizer may be incorporated into the solar panel module 2 or placed in electrical communication with solar panel module 2. The power optimizer assists in limiting the effects of shadowing of the solar panel module 2. In many solar panel module 2 arrangements, if ⅓^{rd} of the panel becomes shadowed, the panel no longer produces any appreciable power. Similarly, if one is employing a series connection, if one string is in shadow, then again all power generation is lost. In the household and commercials settings this can be addressed by planning and tree pruning to eliminate the occurrence of shadows on the solar panel modules 2. However, in a vehicle application, not only is the panel moveable from location to location that might be affected by shadows, but the curvature of the roofline itself may result in reduced energy yields and shadowing effects. In accordance with the present disclosure, bypass diodes may be employed permitting the bypassing of string in instances where a string is in shadows. Alternatively, a DC optimizer may be employed. If one string is in shadows and produces the same voltage as the other strings but only half the current, then the optimizer can reduce the voltage to increase the current from that string using a technique referred to as voltage-current exchange. In such a scenario each string has its own optimizer. The optimizers tune the string output current to match the MPPT—Maximum Power Point Tracking of all of the strings.

The primary setting for incorporating a solar panel module 2 in accordance with the present disclosure is hybrid and electric vehicles. In particular the present disclosure may prove useful for hybrid vehicles by enabling the charging of the auxiliary battery and allow for auxiliary systems such as air conditioning to run off the battery. Hybrid vehicles typically have smaller and lower voltage battery banks (e.g., 48 V), as compared to 300-500 V for electric vehicles. This voltage range and the power output from a solar panel module 2 in accordance with the present disclosure are a better electrical fit for hybrid vehicles than for electric vehicles. As noted above, one use case of the present disclosure is to be able to constantly or periodically or on demand (e.g., 15 min before entry to the vehicle) run the air conditioning system. While this system has a reasonably high power demand, it is one that can be made up by the solar panel module 2 and keep the battery fully charged. Another use case would be to add 5-10 miles of range to an electric vehicle, though as can be appreciated, due to the small roof size, the utility of such a small charging capacity is somewhat limited. An interconnect may be associated with the vehicle to prevent charging when underway. In yet another use case, a parking facility may include a number of plug-in facilities to allow the sale of electricity harvested by the solar panel to the electrical grid, as is done in residential settings.

Although embodiments have been described in detail with reference to the accompanying drawings for the purpose of illustration and description, it is to be understood that the inventive processes and apparatus are not to be construed as limited thereby. It will be apparent to those of ordinary skill in the art that various modifications to the foregoing embodiments may be made without departing from the scope of the disclosure.

We claim:

1. A solar module for incorporation in a motor vehicle comprising:
a front sheet, the front sheet being flat or having a curvature in at least one direction;
at least one set of strings, wherein each string is formed of a plurality of strips of solar cells and each of the strips is arranged in an overlapping manner with an adjacent strip, and each strip is electrically connected to an adjacent strip with an electrically conductive adhesive;
a first encapsulation layer disposed between the front sheet and a first side of the at least one set of strings;
a second encapsulation layer formed on a second side of the at least one set of strings; and
a back sheet formed on the second encapsulation layer.

2. The solar module of claim 1, wherein the plurality strings are electrically connected in parallel.

3. The solar module of claim 1, comprising at least two sets of strings, wherein each set is electrically connected in series.

4. The solar module of claim 1, further comprising a plurality of bypass diodes.

5. The solar module of claim 4, wherein each string includes a bypass diode.

6. The solar module of claim 1, wherein the front sheet is formed of glass.

7. The solar module of claim 1, wherein the back sheet is formed of a flat transparent material.

8. The solar module of claim 7, wherein the back sheet has sufficient flexibility to mold to the profile of the front sheet and the first and second encapsulation layers during a lamination process.

9. The solar module of claim 1, wherein upon lamination the first and second encapsulation layers fill any gaps and voids formed by the overlapping strips or the spacing between adjacent strings.

10. The solar module of claim 9, wherein upon lamination the first and second encapsulation layers adhere the front sheet and back sheet to sets of strings forming a unitary construction for the solar module.

11. The solar module of claim 1, wherein the strips overlap at bus bars formed on a font side and a back side of each strip to create an electrical circuit along the length of the string.

12. The solar module of claim 1, wherein each string electrically connects to a bus bar formed on each end of the solar module.

13. The solar module of claim 1, wherein the sets of strings are arranged to substantially conform to the curvature of the front sheet.

14. The solar module of claim 1, further comprising at least one positive and at least one negative electrical terminal for connection to an electrical storage element of a motor vehicle.

15. The solar module of claim 14, wherein the electrical storage element is a battery.
